(19) United States
(12) Patent Application Publication
(10) Pub. No.: US 2019/0235005 A1
(43) Pub. Date: Aug. 1, 2019

(54) HIGH-TEMPERATURE TESTING DEVICE AND SYSTEM THEREOF

(71) Applicants: HKC Corporation Limited, Shenzhen, Guangdong (CN); Chongqing HKC Optoelectronics Technology Co., Ltd., Chongqing (CN)

(72) Inventor: Cheng-Hang Ho, Chongqing (CN)

(21) Appl. No.: 16/330,097

(22) PCT Filed: Jun. 16, 2017
(86) PCT No.: PCT/CN2017/088680

§ 371 Date: Mar. 3, 2019

(30) Foreign Application Priority Data
May 11, 2017 (CN) 201710330236.5

(51) Int. Cl. G01R 31/00; G01R 31/28

(52) U.S. Cl. CPC G01R 31/003; G01R 31/2875

(57) ABSTRACT

Disclosed are a high-temperature testing device, including a trolley, a furnace and a door body. The trolley includes a base and a display panel placing area defined at the base. The base includes a support table and a protruding block formed on an upper surface of and perpendicular to the support table; the display panel placing area is defined on the protruding block. A power supplier and a signal generator are both defined on the support table. A cavity is formed in the furnace body to match and receive the trolley. A first heat insulating plate and a second heat insulating plate are respectively defined on opposite inner walls at two sides of the furnace body. A gap is defined between opposite end portions of the first heat insulating plate and the second heat insulating plate, for the protruding block to pass through.

### TECHNICAL FIELD

The present application relates to a technical field of display panel, and specifically relates to a high-temperature testing device and system thereof.

### BACKGROUND

In high-temperature test of display panel, for example in the process of high-temperature test, it has not be satisfied that power supplier and signal generator are located externally, since a size of the display panel has increased while the length of power cord and signal cord is still limited. The power supplier and the signal generator have to be suffered to the high-temperature test, together with the display panel. However, life spans of the power supplier and the signal generator will decrease after long exposure of high temperature.

### SUMMARY

Exemplary embodiments of the present application provide a high-temperature testing device and a system thereof, which may form a heat insulated space to avoid an operation of the power supplier and the signal generator under high temperature, and to avoid a decrease of the life span of the power supplier and the signal generator.

In one aspect, exemplary embodiments of the present application provide a high-temperature testing device. The device includes a trolley, including a base and a display panel placing area defined on the base; the base includes a supporting table and a protruding block formed perpendicular to an upper surface of the supporting table; the display panel placing area is defined on the protruding block; a power supplier defined on the supporting table of the trolley to provide testing power for the display panel; a signal generator defined on the supporting table of the trolley to provide a testing signal for the display panel; a furnace body, in which a cavity is formed in the furnace body to match and receive the trolley; a first heat insulating plate and a second heat insulating plate are formed on opposite inner walls at two sides of the furnace body; the first heat insulating plate and the second heat insulating plate are both located above the supporting table; a gap is defined between the opposite end portions of the first heat insulating plate and the second heat insulating plate, for the protruding block to pass through; after the trolley is located inside the furnace body, the protruding block simultaneously abuts against the first heat insulating plate and the second heat insulating plate, and the protruding block is matched to and caught in the gap, allowing both the power supplier and the signal generator to locate under the first heat insulating plate and the second heat insulating plate; and a door body, the door body is movably defined on the furnace body and matched to close the furnace body.

In another aspect, the exemplary embodiments of the present application provides a high-temperature testing system including a control unit, and the control unit is electrically connected to the high-temperature testing device, to control the high-temperature testing device to perform a high-temperature test; the high-temperature testing device includes: a trolley, and the trolley includes a base and a display panel placing area which are defined on the base; the base includes a supporting table and a protruding block formed perpendicular to an upper surface of the supporting table; the display panel placing area is defined on the protruding block; a power supplier, and the power supplier is defined on the supporting table of the trolley; a signal generator, and the signal generator is defined on the supporting table of the trolley; a furnace body, and a cavity is formed in the furnace body to match and receive the trolley; a first heat insulating plate and a second heat insulating plate are formed on opposite inner walls at two sides of the furnace body; the first heat insulating plate and the second heat insulating plate are both located above the supporting table; a gap is defined between opposite end portions of the first heat insulating plate and the second heat insulating plate, for the protruding block to pass through; after the trolley is located inside the furnace body, the protruding block simultaneously abuts against the first heat insulating plate and the second heat insulating plate, and the protruding block is matched to and caught in the gap, allowing the power supplier and the signal generator are simultaneously to locate under the first heat insulating plate and the second heat insulating plate; and a door body, the door body is movably defined on the furnace body and matched to close the furnace body.

The high-temperature testing device and the high-temperature testing system disclosed by the exemplary embodiments of the present application, form the first heat insulating plate and the second heat insulating plate on opposite inner walls at two sides of the furnace body respectively. The first heat insulating plate and the second heat insulating plate are both located above the supporting table, and a gap is defined between the opposite ends of the first heat insulating plate and the second heat insulating plate for the protruding block to pass through. After the trolley is located inside the furnace body, the protruding block simultaneously abuts against the first heat insulating plate and the second heat insulating plate, and the protruding block is matched to and caught in the gap. By matching and fixing of the protruding block with the first heat insulating plate and the second heat insulating plate, the cavity of the furnace body is divided into to two independent compartments. Heat transfer by heat flow is thus prevented between the two compartments. And the power supplier and the signal generator located on the supporting table are insulated from the high temperature environment, avoiding the operation of the power supplier and the signal generator under high temperature. The decrease of the life span of the power supplier and the signal generator is thus prevented.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only about some embodiments of the present invention, and persons of ordinary skill in the art can derive other drawings from the accompanying drawings without creative efforts.

FIG. 1 is a structural schematic view of the high-temperature testing device disclosed in one exemplary embodiment of the present application;

FIG. 2 is a structural schematic view of the trolley disclosed in one exemplary embodiment of the present application;

FIG. 3 is a structural schematic view of the furnace body disclosed in one exemplary embodiment of the present application;

FIG. 4 is a structural schematic view of the high-temperature testing system disclosed in one exemplary embodiment of the present application.

### DETAILED DESCRIPTION OF THE EMBODIMENTS

Technical solutions of exemplary embodiments of the present application are described below with clarity and integrity, combining with the drawings of the exemplary embodiments. Obviously, the exemplary embodiments to be described are only a part of exemplary embodiments of the present application, but not all of them. All other exemplary embodiments which are derived by those skilled in the art based on these exemplary embodiments without doing creative labor should be included in the protection scope of the present application.

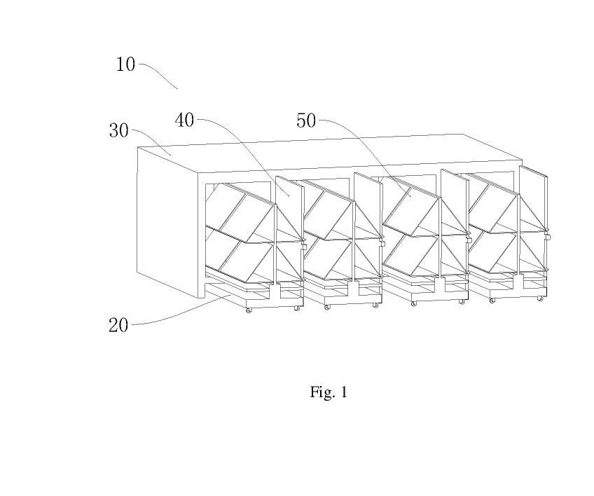

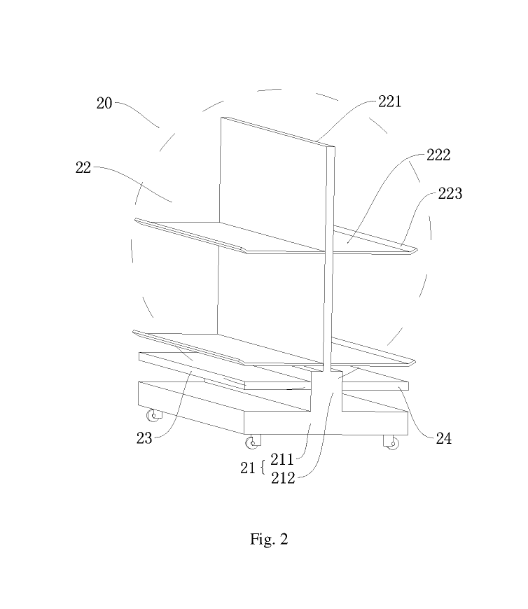

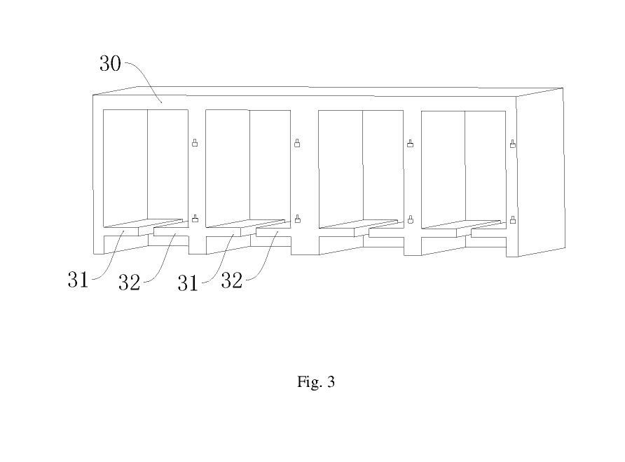

Referring to FIG. 1 to FIG. 3, as can be seen in the figures, the high-temperature testing device 10 includes the trolley 20, the furnace body 30 and the door body 40. The trolley 20 includes the base 21 and the display panel placing area 22 defined on the base 21. The base 21 includes the supporting table 211 and the protruding block 212 formed perpendicular to an upper surface of the supporting table 211. The display panel placing area 22 is defined on the protruding block 212. The power supplier (not shown in the figures) is defined on the supporting table 211 of the trolley 20 and provides testing power for the display panel 50. The signal generator is defined on the supporting table 211 of the trolley 20 and provides the testing signal for the display panel 50. A cavity is formed in the furnace body 30 to match and receive the trolley 20. A first heat insulating plate 31 and a second heat insulating plate 32 are formed on opposite inner walls at two sides of the furnace body 30. The first heat insulating plate 31 and the second heat insulating plate 32 are both located above the supporting table 211. The gap is defined between opposite end portions of the first heat insulating plate 31 and the second heat insulating plate 32, for the protruding block 212 to pass through. After the trolley 20 is located inside the furnace body 30, the protruding block 212 simultaneously abuts against the first heat insulating plate 31 and the second heat insulating plate 32, and the protruding block 212 is matched to and caught in the gap, so that the power supplier and the signal generator are simultaneously located under the first heat insulating plate 31 and the second heat insulating plate 32. The door body 40 is movably defined on the furnace body and is matched to close the furnace body 30.

The display panel placing area 22 is to receive the display panel 50 and to perform the high-temperature test. In the exemplary embodiments of the present application, a number as well as a size of the display panel 50 which is received in the display panel placing area 22 is not limited specifically. For example, the size of the received display panel may range from 21.5 inches to 60 inches. The power supplier provides testing power for the display panel 50 and the signal generator provides testing signal source for the display panel 50. In the exemplary embodiment, the power supplier and the signal generator are received on the supporting table 211, so that they can move anytime and anywhere relatively to the trolley 20, without any power failure of the display panel 50.

The first heat insulating panel 31 and the second heat insulating panel 32 are made of material in which heat is not easily transferred. In some exemplary embodiments, the first heat insulating plate 31 and the second heat insulating plate 32 are formed integrally with the furnace body 30. When the trolley 20 is located in the furnace body 30, the protruding block 212 simultaneously abuts against the first heat insulating plate 31 and the second heat insulating plate 32, matched to and caught in the gap. Thus it can be seen that the furnace body 30 is divided into two independent compartments by means of the first heat insulating plate and the second heat insulating plate. Moreover, heat flow is prevented to transfer between the two compartments so that the power supplier and the signal generator located on the supporting table have been isolated from the high-temperature environment. The operation under high temperature of the power supplier and the signal generator has been avoided. The life span decrease of the power supplier and the signal generator has been prevented.

Understandably, when the trolley 20 is located in the furnace body 30, the first heat insulating plate 31 and the second heat insulating plate 32 are required to abuts simultaneously against to the protruding block 212 so that the protruding block 212 is matched with and caught in the gap. A size, shape and location of the first heat insulating plate 31 and the second heat insulating plate 32 in the furnace body 30 should be not be limited herein. For example, the first heat insulating plate 31 and the second heat insulating plate 32 can be defined symmetrically on the inner walls of the furnace body 30, or the first heat insulating plate 31 and the second heat insulating plate 32 can be defined with a same structure at a different level of the inner wall of the furnace body 30, or the first heat insulating plate 31 and the second heat insulating plate 32 can be defined with a different structure at a same level of the inner wall of the furnace body 30 with no other limitation given herein.

Further, the high-temperature testing device 10 includes a plurality of furnace bodies 30 which are defined adjacently. Each of the furnace bodies corresponds to one trolley 20.

In order to improve testing efficiency, the high-temperature testing device 10 includes a plurality of furnace bodies 30 which are defined adjacently. Each of the furnace bodies 30 corresponds to one trolley 20. In some exemplary embodiments, the high-temperature testing device 10 may include four furnace bodies which are defined adjacently. The temperature in each of the furnace bodies 30 can be controlled independently, which means the temperatures can be different in different furnace bodies 30 in real practice. Display panels 50 with different sizes can be located in different trolleys 20 and different furnace bodies 30 to perform high-temperature tests.

In some exemplary embodiments, the display panel 50 can be a twisted nematic display panel, an in-plane switching screen, a multi-domain vertical alignment panel, a LCD panel, a OLED panel, a QLED panel, or a surface display panel and so on.

Further, the display panel placing area 22 includes a supporting plate 221 defined perpendicular to an upper surface of the protruding block 212, a carrying platform 222 which is defined perpendicular to the supporting table 221 and is symmetrical at two sides of the supporting plate 221. When the display panel 50 is located on the trolley 20, one end of the display panel 50 abuts against the carrying platform 222, and the other end of the display panel abuts and leans against the supporting plate 221.

In order to increase accommodation capacity of the trolley 20 for the display panel 50 and to improve testing efficiency, in one exemplary embodiment of the present application, the display panel placing area 22 includes a supporting plate 221 defined perpendicular to an upper surface of the protruding block 212, a carrying platform 222 which is defined perpendicular to the supporting table 221 and is symmetrical at two sides of the supporting plate 221. For example, a plurality of carrying platforms 222 are defined at a single side of the supporting plate 221, such as two carrying platforms 222 or three carrying platforms 222. The number of the carrying platforms 222 is not limited specifically. In order to enable the display panel 50 to lean against the trolley 20, in one exemplary embodiment of the present application, a constant distance interval is defined between adjacent carrying platforms 222, when a plurality of carrying platforms 222 are defined at a single side of the supporting plate 221. The distance interval, in real practice, would be designed to ensure that the largest size of the display panel 50, such as 60 inches, can be received. So that the display panel 50 is able to lean against the supporting plate 221 with the aid of the carrying platform 222.

Further, two carrying platforms 222 are defined at each side of the supporting plate 221. Two display panels 50 are defined on each of the carrying platforms 222. And the two display panels 50 are non-overlapped.

Specifically, in one exemplary embodiment of the present application, two display panels 50 with the size of, for example, 60 inches are defined on each of the carrying platforms 222. And the two display panels 50 are not located overlapped so to reduce a collision damage between the display panels 50. When two carrying platforms 222 are defined at each side of the supporting plate 221 of the trolley 20, and two 60-inch display panels 50 are defined on each of the carrying platforms 222, the trolley 20 is able to receive 8 pieces of 60-inch display panels 50 in total. Understandably, if the display panels 50 with a size of 21.5 inches to 60 inches are located on the trolley 20 without overlapping, the trolley 20 may receive more than 8 pieces of the display panels 50. Therefore, the trolley 20 is able to receive at least 8 pieces of display panels 50, which means the trolley 20 may at least receive 8 pieces of display panels 50 at a single time.

Further, the anti-slipping structure is defined at an edge of each of the carrying platforms 222 away from the supporting plate 221, to prevent the display panel 50 from dropping.

In order to prevent the display panel 50 from dropping off the carrying platform 222, in one exemplary embodiment of the present application, the anti-slipping structure is defined at an edge of each of the carrying platforms 222 away from the supporting plate 221, to prevent the display panel 50 from dropping, so as to reduce broken damage.

Further, the anti-slipping structure is the bending edge 223. The bending edge 223 and the carrying platform 222 is integrally formed. An obtuse angle is defined between a plane of the bending edge 223 and a plane of the carrying platform 222.

Specifically, in one exemplary embodiment of the present application, the anti-slipping structure is the bending edge 223. An obtuse angle is defined between a plane of the bending edge 223 and a plane of the carrying platform 222. By means of the bending edge 223, after the display panel 50 is located on the trolley 20, one end of the display panel 50 enables to abuts against junction of the bending edge 223 and the carrying platform 222, while the other end of the display panel 50 abuts and leans against the supporting plate 221, so that the display panel 50 is located safely on the trolley 20. The bending edge 223 and the carrying platform 222 is integrally formed, reducing extra manufacturing processes and extra installation operation for the bending edge 223. Understandably, the bending edge 223 may include the whole edge of the carrying platform 222 away from the supporting plate 221. The bending edge 223 covers the whole edge of the carrying platform 222 away from the supporting plate 221. The bending edge 223 can also be defined on the edge of the carrying platform 222 away from the supporting plate 221 with a distance interval, and no specific limitation should be given herein.

Further, the anti-slipping structure are a plurality of polyurethane blocks defined at the edge of the carrying platform 222 away from the supporting plate 221 with a distance interval.

Specifically, in some other exemplary embodiments of the present application, the anti-slipping structure are a plurality of polyurethane blocks (not shown in the figures) defined at an edge of the carrying platform 222 away from the supporting plate 221 with a distance interval. The polyurethane blocks can be fixed on the carrying platform 222 by adhesion. By means of the polyurethane blocks, when the display panel 50 is located on the trolley 20, one end of the display panel 50 enables to abuts against the polyurethane blocks, while the other end of the display panel 50 abuts and lean against the supporting plate 221, so as to prevent the display panel 50 from dropping and to reduce broken damage. Moreover, when the display panel 50 touches with the polyurethane blocks, softness of the polyurethane blocks will prevent surface of the display panel 50 from scratching, ensuring product quality of the display panel 50.

Further, the first heat insulating plate 31 and the second heat insulating plate 32 are symmetrically defined on opposite inner walls at two sides of the furnace body 30.

Specifically, in one exemplary embodiment of the present application, the first heat insulating plate 31 and the second heat insulating plate 32 are symmetrically defined on opposite inner walls at two sides of the furnace body 30, for sake of symmetric structural design and aesthetics of the furnace body 30. Thus, the gap between the end portions of the first heat insulating plate 31 and the second heat insulating plate 32 is exactly located at the middle of the furnace body 30. It provides convenience for the trolley 20 located into the furnace body 30 and increase simplicity and convenience of the operation.

Further, a third heat insulating plate 23 and a fourth heat insulating plate 24 are formed symmetrically at two sides of the protruding block 212. The third heat insulating plate 23 and the fourth heat insulating plate 24 are parallel to the upper surface of the supporting table 211. When the trolley 20 is inside the furnace body 30, the third heat insulating plate 23 is located above the first heat insulating plate 31; and the fourth heat insulating plate 24 is located above the second heat insulating plate 32.

In order to further improve heat insulation, and to prevent the heat flow from transferring between two compartments of the cavity, in one exemplary embodiment of the present application, a third heat insulating plate 23 and a fourth heat insulating plate 24 are formed symmetrically at two sides of the protruding block 212. And the third heat insulating plate 23 and the fourth heat insulating plate 24 are parallel to the upper surface of the supporting table 211. When the trolley 20 is inside the furnace body 30, the third heat insulating plate 23 is located above the first heat insulating plate 31; and the fourth heat insulating plate 24 is located above the second heat insulating plate 32. It has to be noted that no specific limitation of structures of the third heat insulating plate 23 and the four heat insulating plate 24 is given herein. For example, the third heat insulating plate 23 and the four heat insulating plate 24 can be defined at a top end of the protruding block 212 or at the middle portion of the protruding block 212. No matter how the third insulating plate 23 and the fourth insulating plate 24 are structured, the first heat insulating plate 31 is required to be located between the third heat insulating plate 23 and the supporting table 211, and the second heat insulating plate 32 is required to be located between the fourth heat insulating plate 24 and the supporting table 211, so that the heat transfer between the two compartments has been reduced.

Further, a storage space is formed for receiving the power supplier and the signal generator, between lowest carrying platforms 222 at two sides of the supporting plate 221, the third heat insulating plate 23 and the fourth heat insulating plate 24.

Specifically, in one exemplary embodiment of the present application, the third heat insulating plate 23 and the fourth heat insulating plate 24 are formed symmetrically at two sides of the protruding block 212. The third heat insulating plate 23 and the fourth heat insulating plate 24 are also perpendicular to the protruding block 212. The third heat insulating plate 23 and the fourth heat insulating plate 24 are defined between the lowest carrying platform 222 and the supporting table 211. Preset gaps are respectively formed between the third heat insulating plate 23 and the lowest carrying platform 222 and between the fourth heat insulating plate 24 and the lowest carrying platform 222. By means of the preset gaps, storage space is defined for connection cords of the power supplier and the signal generator. Messy placement of the connection cords has thus been prevented. Specific location of the power supplier and the signal generator on the supporting table 211 is defined based on their volume in real practice. The power supplier and the signal generator are located simultaneously on the trolley 20, providing for a continuous testing of the display panel 50. And the display panel 50 is continuously in the testing condition, so that abnormal condition of the display panel 50 can be observed anytime and anywhere.

In one exemplary embodiment of the present application, the first heat insulating plate 31 and the second heat insulating plate 32 are formed on the opposite inner walls of the furnace body 30. The first heat insulating plate 31 and the second heat insulating plate 32 are both defined above the supporting table 211. And a gap is defined between opposite end portions of the first heat insulating plate 31 and the second heat insulating plate 32, for the protruding block 212 to pass through. After the trolley 20 is located inside the furnace body 30, the protruding block 212 simultaneously abuts against the first heat insulating plate 31 and the second heat insulating plate 32, and the protruding block 212 is matched to and caught in the gap. The furnace body 30 is divided into two independent compartments by means of the first heat insulating plate 31 and the second heat insulating plate 32. Heat flow is prevented from transferring between the two compartments so that the power supplier and the signal generator located on the supporting table have been isolated from the high-temperature environment. The operation under high temperature of the power supplier and the signal generator has been avoided. The life span decrease of the power supplier and the signal generator has been prevented.

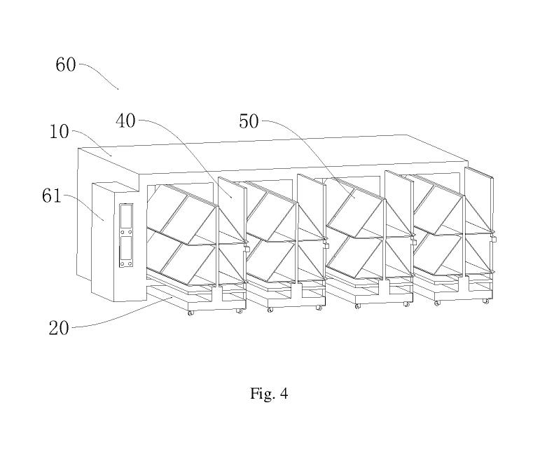

Referring to FIG. 4, as shown in the figure, the high-temperature testing system 60 includes the high-temperature testing device 10 described above; the control unit (not shown in the figure) which is electrically connected with the high-temperature testing device 10, controlling the high-temperature testing device 10 to perform the high temperature test.

Specifically, in one exemplary embodiment of the present application, the high-temperature testing device 10 includes a plurality of furnace bodies 30 which are defined adjacently. Each of the furnace bodies corresponds to one trolley 20. The control unit includes a first control unit 61 and a second control unit 62 (not shown in the figure). The first control unit 61 and the second control unit 62 are respectively defined at two sides of the furnace body 30. The first control unit 61 is electrically connected to one portion of the furnace bodies 30 that are adjacent to the first control unit 61, in order to control a high-temperature test of this portion of the furnace bodies 30; a second control unit 62 is electrically connected to the remaining portion of the furnace bodies 30 that are adjacent to the second control unit 62, in order to control a high-temperature test of two furnace bodies 30. In some exemplary embodiments, the high-temperature testing device 10 may include 4 furnace bodies 30 which are defined adjacently. The first control unit 61 is electrically connected to two furnace bodies 30 that are adjacent to the first control unit 61, in order to control an aging test of these two furnace bodies 30; a second control unit 62 is electrically connected to the other two the furnace bodies 30 that are adjacent to the second control unit 62, in order to control an aging test of the other two furnace bodies 30. It should be noted that, in the above exemplary embodiments, the description of the various exemplary embodiments are emphasized differently, and the parts that are not described in detail in a certain exemplary embodiment may be referred to the related description of other exemplary embodiments.

The above description is only specific exemplary embodiments of the present application, but the protection scope of the present application is not limited thereto. Any equivalents, modifications or substitutions that can be conceived by those skilled in the art within the technical scope disclosed in the present application, should be included within the protection scope of the present application. Therefore, the protection scope of this application should be determined by the claims.

1. A high-temperature testing device, comprising:
a trolley, comprising a base and a display panel placing area defined on the base; the base comprising a supporting table and a protruding block formed perpendicular to an upper surface of the supporting table; the display panel placing area being defined on the protruding block;
a power supplier, defined in the supporting table of the trolley;
a signal generator, defined in the supporting table of the trolley;
a furnace body, in which a cavity being formed to match and to receive the trolley, a first heat insulating plate and a second heat insulating plate being formed on opposite inner walls at two sides of the furnace body, the first heat insulating plate and the second heat insulating plate being both located above the supporting table, and a gap is defined between the opposite ends of the first heat insulating plate and the second heat insulating plate for the protruding block passing through, after the trolley being located inside the furnace body, the protruding block abutting against the first heat insulating plate and the second heat insulating plate, and the protruding block being matched to and caught in the gap; allowing both the power supplier and the signal generator to locate under the first heat insulating plate and the second heat insulating plate; and
a door body, movably defined on the furnace body and matched to close the furnace body.

2. The device of claim 1, wherein the high-temperature testing device comprises a plurality of the furnace bodies that are adjacent with each other; and each of the furnace bodies corresponds to the trolley.

3. The device of claim 1, wherein the display panel placing area comprises a supporting plate defined perpendicular to an upper surface of the protruding block, and carrying platforms which are perpendicular to the supporting table are symmetrically defined at two sides of the supporting plate; when a display panel is located on the trolley, one end of the display panel abuts against the carrying platform, and the other end of the display panel abuts and leans against the supporting plate.

4. The device of claim 3, wherein two carrying platforms are defined at each side of the supporting plate; two display panels are defined on each of the carrying platforms; and the two display panels are non-overlapped.

5. The device of claim 3, wherein an anti-slipping structure is defined at an edge of each of the carrying platforms away from the supporting plate, to prevent the display panel from dropping.

6. The device of claim 5, wherein the anti-slipping structure is a bending edge, the bending edge and the carrying platform is integrally formed, and an obtuse angle is formed between a plane of the bending edge located and a plane of the carrying platform located.

7. The device of claim 5, wherein the anti-slipping structure comprises a plurality of polyurethane blocks defined at an edge of the carrying platform away from the supporting plate at intervals.

8. The device of claim 4, wherein the first heat insulating plate and the second heat insulating plate are symmetrically defined on opposite inner walls at two sides of the furnace body.

9. The device of claim 8, wherein a third heat insulating plate and a fourth heat insulating plate are formed symmetrically at two sides of the protruding block, the third heat insulating plate and the fourth heat insulating plate are parallel to the upper surface of the supporting table; when the trolley is located inside the furnace body, the third heat insulating plate is located above the first heat insulating plate, and the fourth heat insulating plate is located above the second heat insulating plate.

10. The device of claim 9, wherein a storage space is formed for receiving the power supplier and the signal generator, between the lowest carrying platforms at two sides of the supporting plate, and the third heat insulating plate and the fourth heat insulating plate.

11. A high-temperature testing system, comprising
a high-temperature testing device,
a control unit, electrically connected to the high-temperature testing device, to control the high-temperature testing device to perform a high-temperature test;
the high-temperature testing device comprising:
a trolley, comprising a base and a display panel placing area defined on the base; the base comprising a supporting table and a protruding block formed perpendicular to an upper surface of the supporting table; the display panel placing area being defined on the protruding block;
a power supplier, defined in the supporting table of the trolley;
a signal generator, defined in the supporting table of the trolley;
a furnace body, in which a cavity being formed to match and to receive the trolley, a first heat insulating plate and a second heat insulating plate being formed on opposite inner walls at two sides of the furnace body, the first heat insulating plate and the second heat insulating plate being both located above the supporting table, and a gap is defined between the opposite ends of the first heat insulating plate and the second heat insulating plate for the protruding block passing through, after the trolley being located inside the furnace body, the protruding block abutting against the first heat insulating plate and the second heat insulating plate, and the protruding block being matched to and caught in the gap; allowing both the power supplier and the signal generator to locate under the first heat insulating plate and the second heat insulating plate; and
a door body, movably defined on the furnace body and matched to close the furnace body.

12. The system of claim 11, wherein the high-temperature testing device comprises a plurality of furnace bodies that are adjacently with each other; and each of the furnace bodies corresponds to the trolley; the control unit comprising a first control unit and a second control unit, the first control unit and the second control unit being respectively defined at two sides of the furnace body, the first control unit being electrically connected to a portion of the furnace bodies that are adjacent to the first control unit, to control a high-temperature test of the portion of the furnace bodies, the second control unit being electrically connected to the other portion of the furnace bodies that are adjacent to the second control unit, to control a high-temperature test of the other portion of the furnace bodies.

13. The system of claim 11, wherein the display panel placing area comprises a supporting plate defined perpendicular to an upper surface of the protruding block, and carrying platforms which are perpendicular to the supporting table are symmetrically defined at two sides of the supporting plate; when a display panel is located on the trolley, one end of the display panel abuts against the carrying platform, and the other end of the display panel abuts and leans against the supporting plate.

14. The system of claim 13, wherein two carrying platforms are defined at each side of the supporting plate; two display panels are defined on each of the carrying platforms; and the two display panels are non-overlapped.

15. The system of claim 13, wherein an anti-slipping structure is defined at an edge of each of the carrying platforms away from the supporting plate, to prevent the display panel from dropping.

16. The system of claim 15, wherein the anti-slipping structure is a bending edge, wherein the bending edge and the carrying platform is integrally formed; and an obtuse angle is defined between a plane of the bending edge and a plane of the carrying platform located.

17. The system of claim 15, wherein the anti-slipping structure comprises a plurality of polyurethane blocks defined at an edge of the carrying platform away from the supporting plate with at intervals.

18. The system of claim 14, wherein the first heat insulating plate and the second heat insulating plate are symmetrically defined on opposite inner walls at two sides of the furnace body.

19. The system of claim 18, wherein a third heat insulating plate and a fourth heat insulating plate are formed symmetrically at two sides of the protruding block, the third heat insulating plate and the fourth heat insulating plate are parallel to the upper surface of the supporting table; when the trolley is located inside the furnace body, the third heat insulating plate is located above the first heat insulating plate; and the fourth heat insulating plate is located above the second heat insulating plate.

20. The system of claim 19, wherein a storage space is formed for receiving the power supplier and the signal generator, between the lowest carrying platforms at two sides of the supporting plate, the third heat insulating plate and the fourth heat insulating plate.
